(19) United States
(12) Patent Application Publication
(10) Pub. No.: US 2023/0395610 A1
(43) Pub. Date: Dec. 7, 2023

(54) THIN FILM TRANSISTOR AND MANUFACTURING METHOD THEREOF

(71) Applicant: HANNSTAR DISPLAY CORPORATION, Taipei City (TW)

(72) Inventors: Chiung-Chang Wu, Tainan City (TW); Jeng-Long Sheu, Kaohsiung City (TW); Yu-Kai Chuang, Tainan City (TW)

(73) Assignee: HANNSTAR DISPLAY CORPORATION, Taipei City (TW)

(21) Appl. No.: 18/143,083

(22) Filed: May 4, 2023

(30) Foreign Application Priority Data
Jun. 1, 2022 (CN) 202210620953.2

(51) Int. Cl. H01L 27/12

(52) U.S. Cl. CPC H01L 27/1222; H01L 27/127

(57) ABSTRACT

A thin film transistor includes a substrate, a gate, a gate insulating layer, a semiconductor layer, a first conductive layer, a covering layer and a sidewall protection layer. The gate is disposed on the substrate, the gate insulating layer is disposed on the gate, and the semiconductor layer is disposed on the gate insulating layer. The first conductive layer is disposed on the semiconductor layer, and the first conductive layer includes copper. The covering layer is disposed on an upper surface of the first conductive layer, and the covering layer includes copper nitride. The sidewall protection layer is disposed on a side surface of the first conductive layer, and the sidewall protection layer includes copper nitride.

### BACKGROUND OF THE INVENTION

### 1. Field of the Invention

The present invention relates to a thin film transistor and a manufacturing method thereof, and more particularly to a thin film transistor and a manufacturing method thereof using copper as a material of conductive lines or electrodes.

### 2. Description of the Prior Art

In large-size display panels, copper is used as the material of conductive lines or electrodes in order to enhance the carrier mobility of thin film transistors. However, the oxidation or diffusion of copper may cause the electrical characteristics of thin film transistors unstable, which leads to poor display quality of the display panel.

### SUMMARY OF THE INVENTION

The technical problem to be solved by the present invention is that when copper is used as the material of the conductive lines or electrodes of the thin film transistors in the display panel, the oxidation or diffusion of copper causes the electrical characteristics of the thin film transistors to be unstable.

To solve the above technical problem, the present invention provides a manufacturing method of a thin film transistor which includes following steps: providing a substrate; forming a gate on the substrate; forming a gate insulating layer on the gate; forming a semiconductor layer on the gate insulating layer; forming a source/drain conductive layer on the gate insulating layer and the semiconductor layer, the source/drain conductive layer includes a first conductive layer and a covering layer, the covering layer is disposed on an upper surface of the first conductive layer, the first conductive layer includes copper, and the covering layer includes copper nitride; and performing a patterning process to form a trench in the source/drain conductive layer, and the trench penetrates through the source/drain conductive layer.

To solve the above technical problem, the present invention also provides a method for manufacturing a thin film transistor which includes following steps: providing a substrate; forming a gate on the substrate; forming a gate insulating layer on the gate; forming a semiconductor layer on the gate insulating layer; forming a source/drain conductive layer on the gate insulating layer and the semiconductor layer, the source/drain conductive layer includes a first conductive layer, and the first conductive layer includes copper; performing a patterning process to form a trench in the source/drain conductive layer, and the trench penetrates through the source/drain conductive layer; and performing a nitridation treatment, the nitridation treatment forms a covering layer on an upper surface of the first conductive layer, the covering layer includes copper nitride, and the nitridation treatment is performed after the patterning process is performed.

To solve the above technical problem, the present invention provides a thin film transistor which includes a substrate, a gate, a gate insulation layer, a semiconductor layer, a drain and a source, and each of the drain and the source includes a first conductive layer and a covering layer. The gate is disposed on the substrate, the gate insulating layer is disposed on the gate, and the semiconductor layer is disposed on the gate insulating layer. The first conductive layer is disposed on the semiconductor layer and the gate insulating layer, and the first conductive layer includes copper. The covering layer is disposed on an upper surface of the first conductive layer, and the covering layer includes copper nitride.

In the thin film transistor and the manufacturing method thereof of the present invention, the copper nitride layer is formed above, below or on the side surface of the copper layer of the source and drain as the covering layer, the barrier layer or the sidewall protection layer, which can mitigate the oxidation and diffusion of copper and further improve the electrical characteristics of the thin film transistor. Using the copper nitride layer as the covering layer or barrier layer can prevent the edge of the covering layer or barrier layer from forming the chamfer due to etching and reduce the holes or cracks in the thin film transistor, thereby improving the reliability of the thin film transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 are schematic cross-sectional diagrams illustrating a manufacturing method of a thin film transistor according to a first embodiment of the present invention.

FIG. 9 is a flowchart of the manufacturing method of the thin film transistor according to the present invention.

FIG. 10 to FIG. 13 are schematic cross-sectional diagrams of a manufacturing method of a thin film transistor according to a second embodiment of the present invention.

FIG. 14 to FIG. 17 are schematic cross-sectional diagrams of a manufacturing method of a thin film transistor according to a first variant embodiment of the first embodiment or a first variant embodiment of the second embodiment of the present invention.

FIG. 18 to FIG. 21 are schematic cross-sectional diagrams of a manufacturing method of a thin film transistor according to a second variant embodiment of the first embodiment of the present invention.

FIG. 22 to FIG. 24 are schematic cross-sectional diagrams of a manufacturing method of a thin film transistor according to a second variant embodiment of the second embodiment of the present invention.

### DETAILED DESCRIPTION

To provide a better understanding of the present invention to those skilled in this field, preferred embodiments will be detailed as follows. The preferred embodiments of the present invention are illustrated in the accompanying drawings to elaborate on the contents and effects to be achieved. It should be noted that the drawings are simplified schematics, and therefore show only the components and combinations associated with the present invention, so as to provide a clearer description of the basic architecture or method of implementation. The components would be complex in reality. In addition, for ease of explanation, the components shown in the drawings may not represent their actual number, shape, and dimensions; details can be adjusted according to design requirements.

A direction DR1 and a direction DR2 are shown in the following drawings. The direction DR2 may be perpendicular to a surface 100F of a substrate 100, the direction DR1 may be parallel to the surface 100F of the substrate 100, and the direction DR2 may be perpendicular to the direction DR1. The spatial relationship of structures can be described according to the directions DR1 and DR2 in the following drawings.

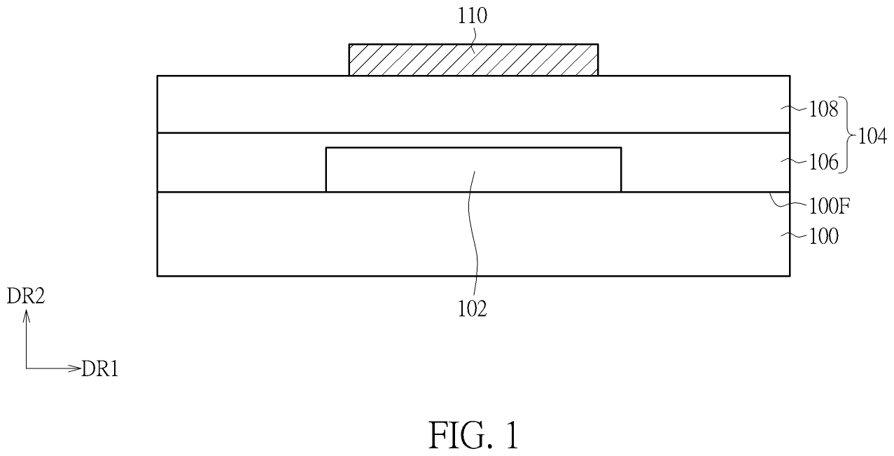

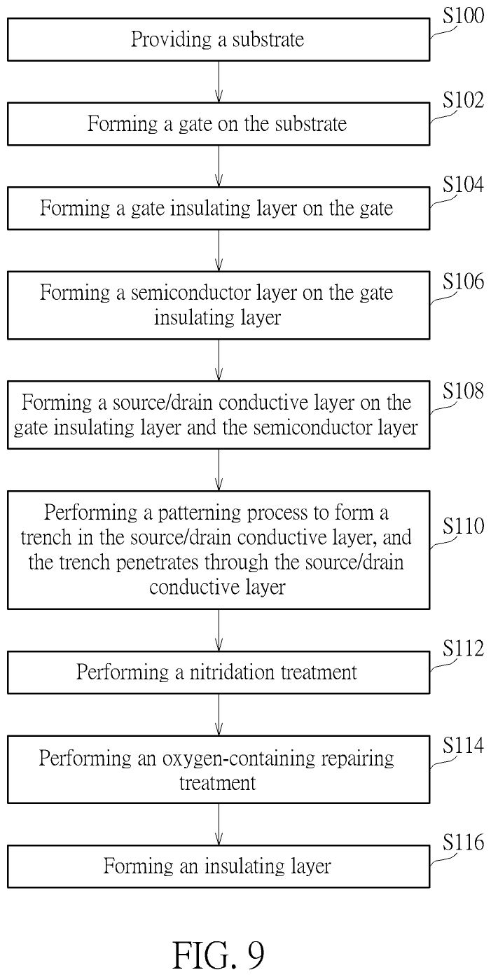

Referring to FIG. 1 to FIG. 9, FIG. 1 to FIG. 8 are schematic cross-sectional diagrams illustrating a manufacturing method of a thin film transistor according to a first embodiment of the present invention, and FIG. 9 is a flowchart of the manufacturing method of the thin film transistor according to the present invention. The manufacturing method of the thin film transistor of this embodiment includes following steps. As shown in FIG. 1 and FIG. 9, a step S100 is first performed to provide the substrate 100. The substrate 100 may be a rigid substrate such as a glass substrate, a plastic substrate, a quartz substrate or a sapphire substrate, but the material of the rigid substrate is not limited thereto. The substrate 100 may also be a flexible substrate such as polyimide (PI) substrate or polyethylene terephthalate (PET) substrate, but the material of the flexible substrate is not limited thereto.

Next, a step S102 is performed to form a gate 102 on the substrate 100. For example, a conductive layer may be formed on the surface 100F of the substrate 100, and a photolithography-etching process may be performed on the conductive layer to form the gate 102, but not limited thereto. In this disclosure, the photolithography-etching process may for example include forming a photoresist on a material layer (such as the above-mentioned conductive layer), exposing the photoresist by a light source through a mask, developing the photoresist to pattern the photoresist, and etching the material layer with the patterned photoresist as a mask to pattern the material layer (for example, patterning the conductive layer to form the gate 102). The gate 102 may include conductive materials, such as metal, but not limited thereto.

Next, a step S104 is performed to form a gate insulating layer 104 on the gate 102. For example, the gate insulating layer 104 may be disposed on the gate 102 and the surface 100F of the substrate 100, but not limited thereto. In some embodiments, the gate insulating layer 104 may include an insulating layer 106 and an insulating layer 108. The insulating layer 106 may be disposed on the gate 102 and the surface 100F of the substrate 100, the insulating layer 108 may be disposed on the insulating layer 106, and the insulating layer 106 may be disposed between the substrate 100 and the insulating layer 108, but not limited thereto. In some embodiments, the gate insulating layer 104 may include only one insulating layer.

The insulating layer 106 or the insulating layer 108 may include inorganic insulating materials, such as silicon oxide, silicon nitride or a combination of the above, but not limited thereto. For example, the insulating layer 108 includes silicon oxide and the insulating layer 106 includes silicon nitride. Other layers or devices may be disposed between the gate insulating layer 104 and the substrate 100 or between the gate 102 and the substrate 100.

Next, a step S106 is performed to form a semiconductor layer 110 on the gate insulating layer 104. For example, a semiconductor material layer may be formed on the gate insulating layer 104 (such as the insulating layer 108) first, and the photolithography-etching process may be performed on the semiconductor material layer to form the semiconductor layer 110, but not limited thereto. In the present invention, the semiconductor layer 110 may include metal oxide semiconductor, such as indium gallium zinc oxide (IGZO), indium zinc oxide (IZO) or a combination of the above, but the material of the metal oxide semiconductor is not limited thereto.

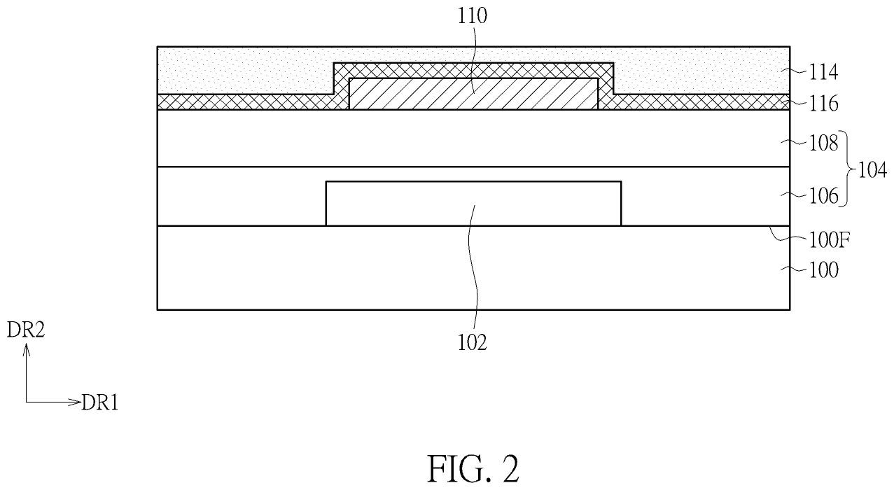

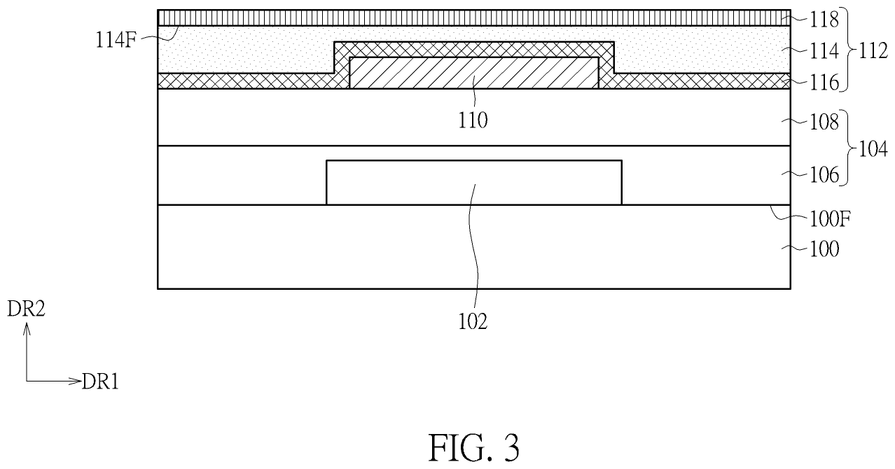

Next, as shown in FIG. 2, FIG. 3 and FIG. 9, a step S108 is performed to form a source/drain conductive layer 112 on the gate insulating layer 104 and the semiconductor layer 110. As shown in FIG. 2, a conductive layer 116 can be formed on the gate insulating layer 104 and the semiconductor layer 110, and the conductive layer 116 includes molybdenum, but not limited thereto. The conductive layer 116 may include other suitable metals or alloys. Then, a conductive layer 114 can be formed on the conductive layer 116, and the conductive layer 114 includes copper. In this disclosure, the conductive layer 114 may be referred to as the first conductive layer 114 and the conductive layer 116 may be referred to as the second conductive layer 116. The conductive layer 114 and the conductive layer 116 can be formed by a physical vapor deposition process, but not limited thereto.

In some embodiments, the conductive layer 114 and the conductive layer 116 can be formed by the same physical vapor deposition apparatus, and a copper target and a molybdenum target can be provided in the same chamber to respectively form the conductive layer 114 and the conductive layer 116, but not limited thereto. In some embodiments, the conductive layer 114 and the conductive layer 116 can be formed by the same physical vapor deposition apparatus, but the conductive layer 114 and the conductive layer 116 can be formed in different chambers. In some embodiments, the conductive layer 114 and the conductive layer 116 can be formed by different physical vapor deposition apparatus.

As shown in FIG. 3, a covering layer 118 is formed on the conductive layer 114, and the covering layer 118 includes copper nitride. In this embodiment, the source/drain conductive layer 112 includes the conductive layer 116, the conductive layer 114 and the covering layer 118. In some embodiments, a reactive physical vapor deposition process can be performed to form the covering layer 118 on an upper surface 114F of the conductive layer 114, but not limited thereto.

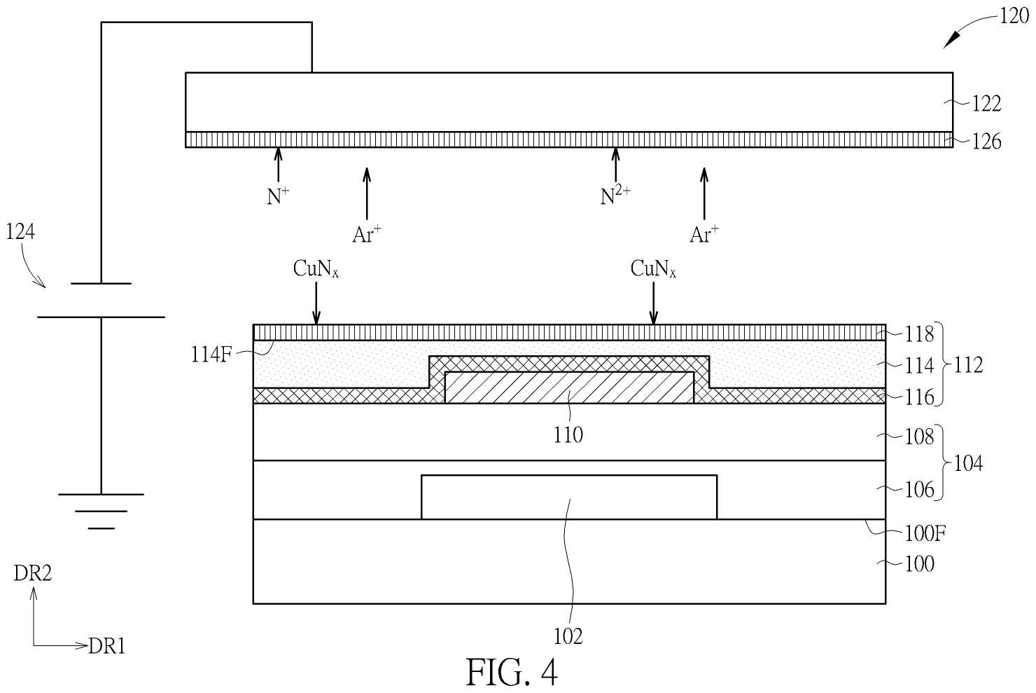

For example, as shown in FIG. 2 and FIG. 4, after the structure in FIG. 2 is formed, the process of forming the covering layer 118 on the upper surface 114F of the conductive layer 114 of FIG. 2 by the reactive physical vapor deposition process 120 may include following steps. A copper target 122 is provided, the copper target 122 can be electrically connected to the cathode of a power supply device 124, and the anode of the power supply device 124 can be grounded. Nitrogen (such as nitrogen gas) is provided and can be used as a reaction gas to form copper nitride on the copper target 122. As shown in FIG. 4, nitrogen ions N⁺ or N⁺² can react with the surface layer on the surface of the copper target 122 to form a copper nitride film 126. Argon (such as argon gas) is provided and can be used as sputtering gas to bombard the copper nitride (such as the copper nitride film 126) on the copper target 122 with argon ions Art Therefore, the copper nitride CuNₓ is deposited on the upper surface 114F of the conductive layer 114, and the covering layer 118 can be formed on the upper surface 114F of the conductive layer 114.

The reactive physical vapor deposition process 120 can be performed in the physical vapor deposition apparatus. In some embodiments, the reactive physical vapor deposition process 120 and the step of forming the conductive layer 114 can be performed in the same physical vapor deposition apparatus and in the same chamber having the copper target, but not limited thereto. For example, after the conductive layer 114 is formed in the physical vapor deposition apparatus, the covering layer 118 is formed on the upper surface 114F of the conductive layer 114 by the reactive physical vapor deposition process 120 in the same vacuum condition. Therefore, the manufacturing time and cost can be saved.

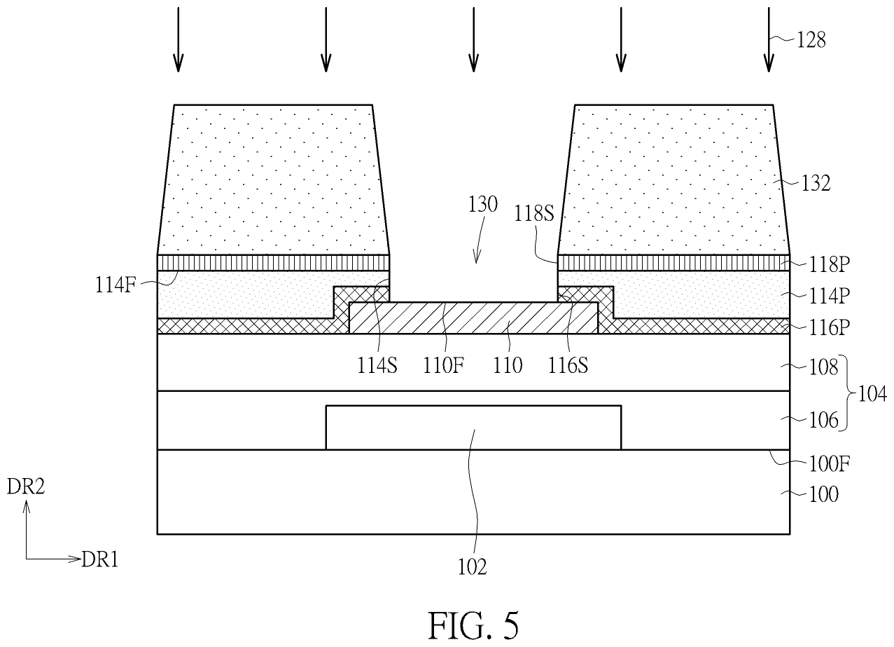

Next, as shown in FIG. 5 and FIG. 9, a step S110 is performed to perform a patterning process 128 on the source/drain conductive layer 112 to pattern the conductive layers 114 and 116 and the covering layer 118 to respectively form the conductive layers 114P and 116P and the covering layer 118P. The patterning process 128 forms a trench 130 in the source/drain conductive layer 112. The trench 130 penetrates through the source/drain conductive layer 112 (i.e., penetrating through the conductive layers 114 and 116 and the covering layer 118), and the trench 130 exposes a side surface 114S of the conductive layer 114P, a side surface 116S of the conductive layer 116P, a side surface 118S of the covering layer 118P and a portion of an upper surface 110F of the semiconductor layer 110.

The patterning process 128 may include the photolithography-etching process. For example, a patterned photoresist 132 may be formed on the source/drain conductive layer 112 (i.e., formed on the covering layer 118) by the photolithography process of the patterning process 128. The patterned photoresist 132 may have an opening, and the opening corresponds to the location where the trench 130 is formed. The trench 130 may be formed by the etching process of the patterning process 128, and the trench 130 may penetrate through the conductive layers 114 and 116 and the covering layer 118 and may expose a portion of the upper surface 110F of the semiconductor layer 110. The patterned photoresist 132 can be removed after the patterning process 128. In this disclosure, the conductive layers 114 and 116 and the covering layer 118 have yet been etched can also be respectively referred to as the conductive material layers 114 and 116 and the covering material layer 118.

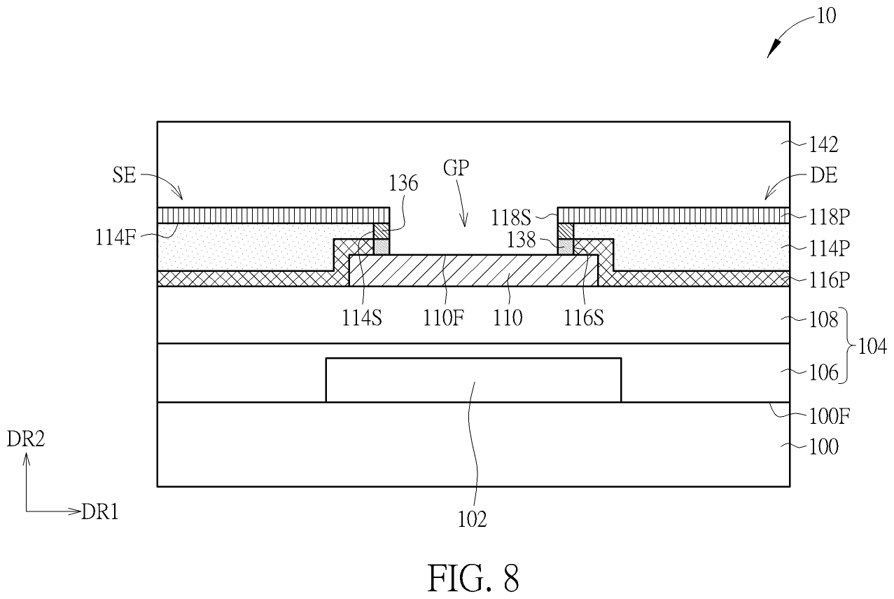

Next, the advantages of the covering layer 118 including copper nitride in this embodiment will be explained. For example, if the covering layer 118 includes molybdenum, the edge of the covering layer 118P adjacent to the trench 130 may form a chamfer after the etching process for forming the trench 130 is performed since the etching rates of molybdenum and copper are different. Therefore, when an insulating layer 142 is formed in the subsequent step S116 (referring to FIG. 8 and FIG. 9), holes or cracks are easily formed in the insulating layer 142 in the trench 130 since the chamfer of the edge of the covering layer 118P may be not completely filled in with the insulating layer 142, thereby decreasing reliability of the thin film transistor. However, when the covering layer 118 includes copper nitride, the chamfer can be prevented from forming on the edge of the covering layer 118P adjacent to the trench 130 after the etching process for forming the trench 130 is performed since the etching rates of copper nitride and copper are relatively close, thereby improving the reliability of the thin film transistor.

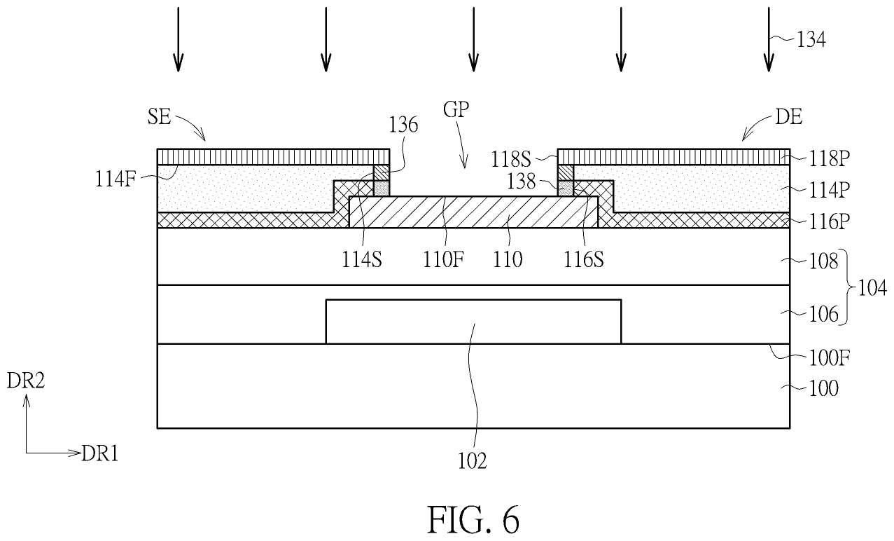

Next, as shown in FIG. 6 and FIG. 9, a step S112 is performed to perform a nitridation treatment 134. The nitridation treatment 134 forms a sidewall protection layer 136 on the side surface 114S of the conductive layer 114P and a sidewall protection layer 138 on the side surface 116S of the conductive layer 116P. In this disclosure, the sidewall protection layer 136 may be referred to as the first sidewall protection layer, and the sidewall protection layer 138 may be referred to as the second sidewall protection layer. The sidewall protection layer 136 includes copper nitride and the sidewall protection layer 138 includes molybdenum nitride, but the material of the sidewall protection layer 138 is not limited thereto. After the step S112 is performed, the fabrication of the drain DE and the source SE of the thin film transistor may be completed. The drain DE and the source SE are opposite to each other and a gap GP is located between the drain DE and the source SE, and each of the drain DE and the source SE can include the conductive layers 114P, 116P, the covering layer 118P and the sidewall protection layers 136, 138.

The nitridation treatment 134 can be performed in a chemical vapor deposition apparatus, and the nitridation treatment 134 can include providing argon (such as argon gas) first and providing nitrogen (such as nitrogen gas) next to form the sidewall protection layer 136 and the sidewall protection layer 138 in a plasma environment. The temperature of the plasma environment may be less than 220° C., but not limited thereto. Argon can be provided first to remove pollutants on the side surface 114S of the conductive layer 114P and the side surface 116S of the conductive layer 116P and activate the bonding on the side surface 114S and the side surface 116S. Next, nitrogen is provided, and dissociated nitrogen ions react with copper on the side surface 114S of the conductive layer 114P to form copper nitride (i.e., the sidewall protection layer 136), and the dissociated nitrogen ions react with molybdenum on the side surface 116S of the conductive layer 116P to form molybdenum nitride (i.e., the sidewall protection layer 138).

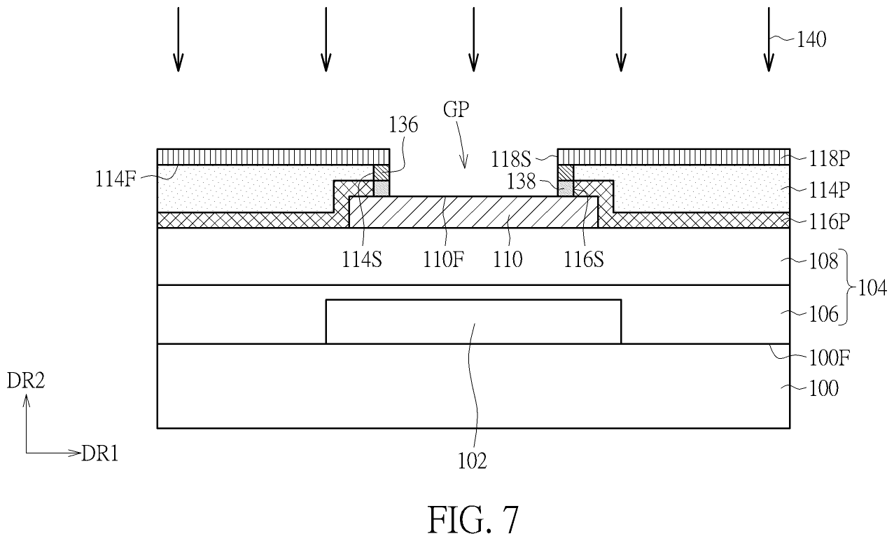

Next, as shown in FIG. 7 and FIG. 9, a step S114 is performed to perform an oxygen-containing repairing treatment 140. Since the upper surface 110F of the semiconductor layer 110 may be damaged in the etching process of the patterning process 128 used to form the trench 130 (referring to FIG. 5), the oxygen-containing repairing treatment 140 can be performed to repair defects in the semiconductor layer 110. In the oxygen-containing repairing treatment 140, an oxygen-containing gas may be provided for repairing the semiconductor layer 110. The oxygen-containing gas may include oxygen or nitrous oxide, but not limited thereto. In addition, the oxygen-containing repairing treatment 140 can be performed in the chemical vapor deposition apparatus. Therefore, the steps of nitridation treatment 134 and the oxygen-containing repairing treatment 140 can be sequentially performed in the same chemical vapor deposition apparatus for saving the manufacturing time and cost.

Since the oxygen-containing repairing treatment 140 is performed after the nitridation treatment 134 is performed (i.e., after the sidewall protection layer 136 and the sidewall protection layer 138 is formed), the covering layer 118P and the sidewall protection layer 136 have been respectively formed on the upper surface 114F and the side surface 114S of the conductive layer 114P, and the sidewall protection layer 138 has been formed on the side surface 116S of the conductive layer 116P when the oxygen-containing repairing treatment 140 is performed. The covering layer 118P and the sidewall protection layer 136 can be used as an oxidation prevention layer of the conductive layer 114P, and the sidewall protection layer 138 can be used as the oxidation prevention layer of the conductive layer 116P, and oxygen molecules can be prevented from reacting with the conductive layers 114P and 116P. Therefore, the oxidation of copper in the conductive layer 114P and the oxidation of molybdenum in the conductive layer 116P in the oxygen-containing repairing treatment 140 can be mitigated, thereby improving the electrical characteristics of the thin film transistor.

Next, as shown in FIG. 8 and FIG. 9, a step S116 is performed to form an insulating layer 142. The insulating layer 142 is disposed on the drain DE, the source SE and the semiconductor layer 110 and in the gap GP between the drain DE and the source SE. The insulating layer 142 is disposed in the gap GP and covers the semiconductor layer 110 including metal oxide semiconductor, thus the insulating layer 142 may include an insulating material including oxygen, but not limited thereto. The material of the insulating layer 142 may for example include silicon oxide, aluminum oxide or titanium oxide, but not limited thereto.

Although the insulating layer 142 including oxygen is disposed on the drain DE and the source SE and in the gap GP between the drain DE and the source SE, the covering layer 118P and the sidewall protection layer 136 can be used as the oxidation prevention layer of the conductive layer 114P to mitigate the oxidation of copper in the conductive layer 114P. Similarly, the sidewall protection layer 138 can be used as the oxidation prevention layer of the conductive layer 116P to mitigate the oxidation of molybdenum in the conductive layer 116P. The covering layer 118P and the sidewall protection layer 136 can also mitigate the diffusion of copper in the conductive layer 114P. Therefore, the electrical characteristics of the thin film transistor can be improved.

In addition, the insulating layer 142 can be formed in the chemical vapor deposition apparatus. Therefore, the step of nitridation treatment 134, the step of oxygen-containing repairing treatment 140 and the step of forming the insulating layer 142 can be sequentially performed in the same chemical vapor deposition apparatus, thereby saving the manufacturing time and cost.

In this embodiment, the manufacturing method of the thin film transistor includes the nitridation treatment 134, and the nitridation treatment 134 is performed after the patterning process 128 is performed. The nitridation treatment 134 can form the sidewall protection layer 136 including copper nitride on the side surface 114S of the conductive layer 114P including copper. In addition, the nitridation treatment 134 is performed before the oxygen-containing repairing treatment 140 and the step of forming oxygen-containing insulating layer 142 is performed, the sidewall protection layer 136 can prevent the oxygen in the oxygen-containing repairing treatment 140 and the oxygen in the insulating layer 142 from entering the conductive layer 114P from the side surface 114S of the conductive layer 114P, and the oxidation of copper can be mitigated.

Specifically, in this embodiment, the covering layer 118P and the sidewall protection layer 136 including copper nitride are used as the oxidation prevention layer of the conductive layer 114P and respectively formed on the upper surface 114F and the side surface 114S of the conductive layer 114P including copper, so as to prevent the upper surface 114F and the side surface 114S of the conductive layer 114P from reacting with oxygen, thereby mitigating the oxidation of copper in the conductive layer 114P and further improving the electrical characteristics of the thin film transistor.

As shown in FIG. 8, a thin film transistor 10 of this embodiment can include the substrate 100, the gate 102, the gate insulating layer 104, the semiconductor layer 110, the conductive layer 114P, the covering layer 118P, the sidewall protection layer 136 and the insulating layer 142. The gate 102 is disposed on the substrate 100, the gate insulating layer 104 is disposed on the gate 102, and the semiconductor layer 110 is disposed on the gate insulating layer 104. The conductive layer 114P is disposed on the semiconductor layer 110 and the gate insulating layer 104, and the conductive layer 114P includes copper. The covering layer 118P is disposed on the upper surface 114F of the conductive layer 114P, and the covering layer 118P includes copper nitride. The sidewall protection layer 136 is disposed on the side surface 114S of the conductive layer 114P, and the sidewall protection layer 136 includes copper nitride.

The thin film transistor 10 further includes the conductive layer 116P disposed between the conductive layer 114P and the semiconductor layer 110 and between the conductive layer 114P and the gate insulating layer 104, and the conductive layer 116P includes molybdenum. The conductive layer 116P can be used as a barrier layer of the conductive layer 114P to mitigate the diffusion of copper in the conductive layer 114P. The thin film transistor 10 further includes the sidewall protection layer 138 disposed on the side surface 116S of the conductive layer 116P, and the sidewall protection layer 138 includes molybdenum nitride.

In some embodiments, one of the drain DE and the source SE includes the conductive layer 116P, the conductive layer 114P, the covering layer 118P, the sidewall protection layer 136 and the sidewall protection layer 138 disposed on one side of the semiconductor layer 110, and the other one of the drain DE and the source SE includes another conductive layer 116P, another conductive layer 114P, another covering layer 118P, another sidewall protection layer 136 and another sidewall protection layer 138 disposed on the other side of the semiconductor layer 110, and the drain DE and the source SE respectively couple to one side of the semiconductor layer 110 and the other side of the semiconductor layer 110

The gap GP is disposed between the drain DE and the source SE, the sidewall protection layer 136 is disposed between the conductive layer 114P and the gap GP in the direction DR1, and the sidewall protection layer 138 is disposed between the conductive layer 116P and the gap GP in the direction DR1.

The thin film transistor 10 further includes the insulating layer 142 disposed on a portion of the upper surface 110F of the semiconductor layer 110 and the covering layer 118P and filled in the gap GP between the drain DE and the source SE. The sidewall protection layer 136 is disposed between the conductive layer 114P and the insulating layer 142 in the direction DR1, and the sidewall protection layer 138 is disposed between the conductive layer 116P and the insulating layer 142 in the direction DR1.

The thin film transistor and the manufacturing method thereof of the present invention are not limited to the aforementioned embodiments. The following will continue to disclose other embodiments of the present invention. However, in order to simplify the description and highlight the differences between the embodiments, the same reference numerals are used to denote the same elements hereinafter, and the repeated portions will not be described again.

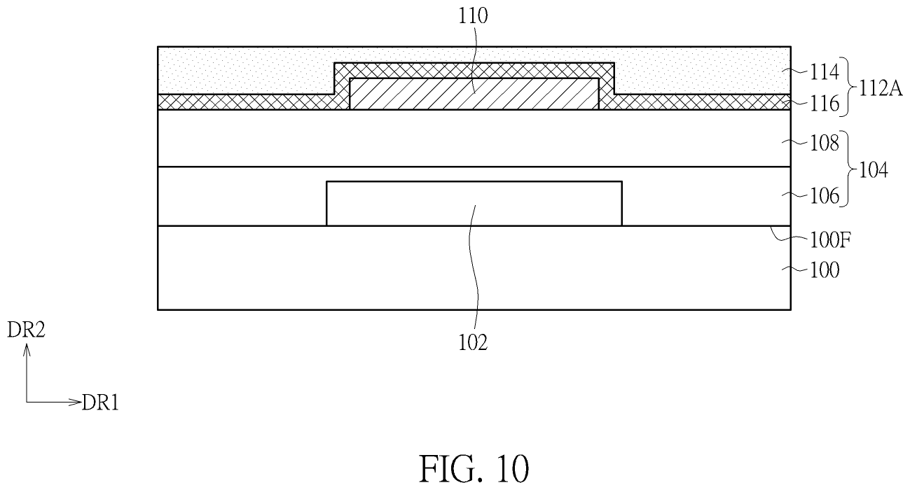

Referring to FIG. 10 to FIG. 13, FIG. 10 to FIG. 13 are schematic cross-sectional diagrams of a manufacturing method of a thin film transistor according to a second embodiment of the present invention, and the flowchart of the manufacturing method of the thin film transistor according to the second embodiment can also refer to FIG. 9. As shown in FIG. 9, the steps S100, S102, S104 and S106 can be performed, and the schematic cross-sectional diagrams corresponding to the steps S100, S102, S104 and S106 of this embodiment can refer to FIG. 1.

Next, as shown in FIG. 10 and FIG. 9, the step S108 is performed to form a source/drain conductive layer 112A on the gate insulating layer 104 and the semiconductor layer 110, and the source/drain conductive layer 112A includes the conductive layer 114 and the conductive layer 116. Comparing to the source/drain conductive layer 112 including the conductive layers 114 and 116 and the covering layer 118 in the first embodiment, the source/drain conductive layer 112A in this embodiment does not include the covering layer 118.

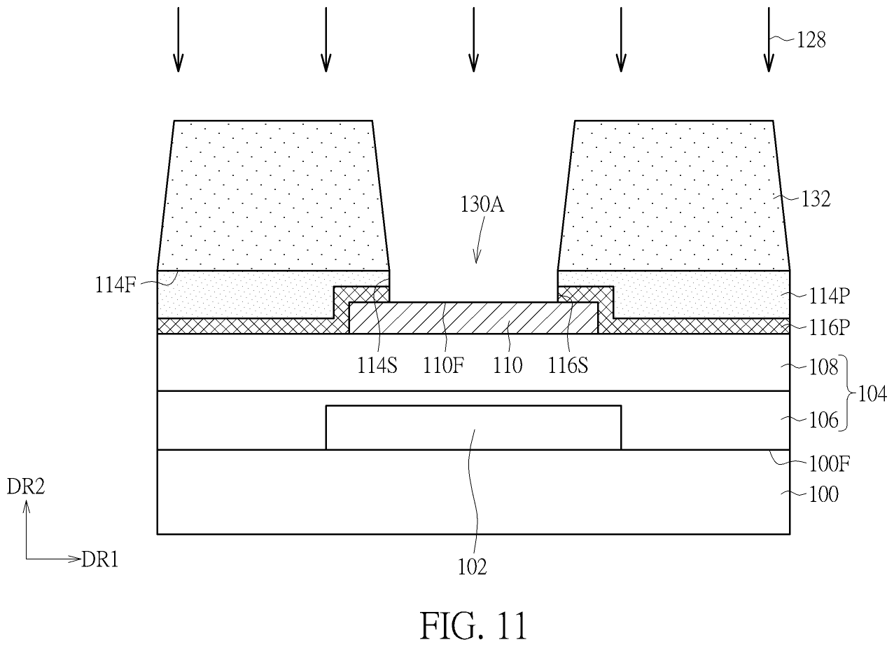

Next, as shown in FIG. 11 and FIG. 9, the step S110 is performed, and the patterning process 128 is performed on the source/drain conductive layer 112A to pattern the conductive layers 114 and 116 to respectively form the conductive layers 114P and 116P. The patterning process 128 forms the trench 130A in the source/drain conductive layer 112A, and the trench 130A penetrates through the source/drain conductive layer 112A (i.e., penetrating through the conductive layers 114 and 116).

In this embodiment, the patterning process 128 may include the photolithography-etching process. For example, the patterned photoresist 132 can be formed on the source/drain conductive layer 112A (i.e., formed on the conductive layer 114) by the photolithography process of the patterning process 128. The patterned photoresist 132 may have an opening corresponding to the location where the trench 130A is formed. The trench 130A may be formed by the etching process of the patterning process 128. The trench 130A penetrates through the conductive layers 114 and 116 of the source/drain conductive layer 112A, and the trench 130A exposes the side surface 114S of the conductive layer 114P, the side surface 116S of the conductive layer 116P and a portion of the upper surface 110F of the semiconductor layer 110. The patterned photoresist 132 can be removed after the patterning process 128.

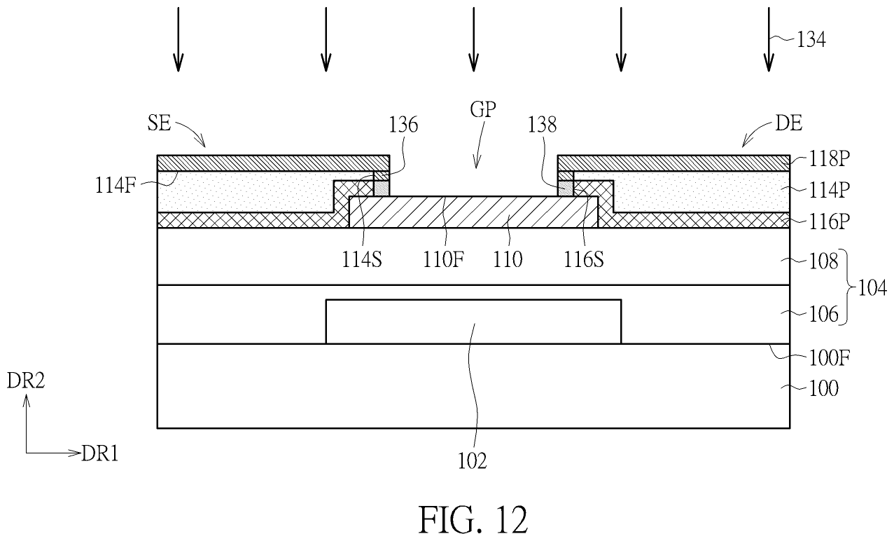

Next, as shown in FIG. 12 and FIG. 9, the step S112 is performed to perform the nitridation treatment 134. The nitridation treatment 134 can simultaneously form the covering layer 118P on the upper surface 114F of the conductive layer 114P and the sidewall protection layer 136 on the side surface 114S of the conductive layer 114P, and each of the covering layer 118P and the sidewall protection layer 136 includes copper nitride. Similar to the first embodiment, the nitridation treatment 134 can be performed in the chemical vapor deposition apparatus, and the nitridation treatment 134 includes providing argon first and providing nitrogen next in the plasma environment to form the covering layer 118P and the sidewall protection layer 136.

In the first embodiment, the process of forming the covering layer 118 on the upper surface 114F of the conductive layer 114 is performed before the patterning process 128, and the patterning process 128 patterns the covering layer 118 to form the covering layer 118P. However, in this embodiment, the process of forming the covering layer 118 on the upper surface 114F of the conductive layer 114 before the patterning process 128 is not required, the covering layer 118P can be formed on the upper surface 114F of the conductive layer 114P and the sidewall protection layer 136 can be formed on the side surface 114S of the conductive layer 114P simultaneously by the nitridation treatment 134. Therefore, the manufacturing time and cost can further be saved in this embodiment comparing to the first embodiment.

In addition, the sidewall protection layer 138 can also be formed on the side surface 116S of the conductive layer 116P in the nitridation treatment 134, and the sidewall protection layer 138 includes molybdenum nitride, but the material of the sidewall protection layer 138 is not limited thereto. After the nitridation treatment 134 is performed, the fabrication of the drain DE and the source SE of the thin film transistor may be completed. The drain DE and the source SE are opposite to each other and the gap GP is located between the drain DE and the source SE, and each of the drain DE and the source SE can include the conductive layers 114P, 116P, the covering layer 118P, and the sidewall protection layers 136, 138.

In the nitridation treatment 134, argon may be provided first to remove the pollutants on the upper surface 114F and side surface 114S of the conductive layer 114P and the side surface 116S of the conductive layer 116P and activate the bonding on the upper surface 114F, the side surface 114S and the side surface 116S. Next, nitrogen is provided, and the dissociated nitrogen ions react with copper on the upper surface 114F and the side surface 114S of the conductive layer 114P to form copper nitride (i.e., the covering layer 118P and the sidewall protection layer 136), and the dissociated nitrogen ions react with molybdenum on the side surface 116S of the conductive layer 116P to form molybdenum nitride (i.e., the sidewall protection layer 138).

Next, as shown in FIG. 9, the step S114 is performed to perform the oxygen-containing repairing treatment 140. The schematic cross-sectional diagram corresponding to the step S114 of this embodiment can refer to FIG. 7 of the first embodiment.

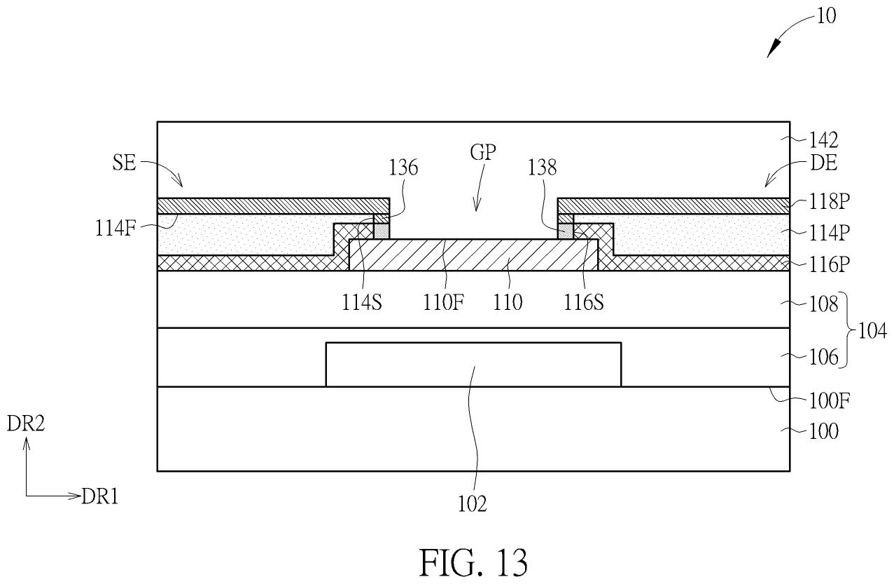

Next, as shown in FIG. 13 and FIG. 9, the step S116 is performed to form the insulating layer 142. The insulating layer 142 is disposed on the drain DE, the source SE and the semiconductor layer 110 and in the gap GP between the drain DE and the source SE.

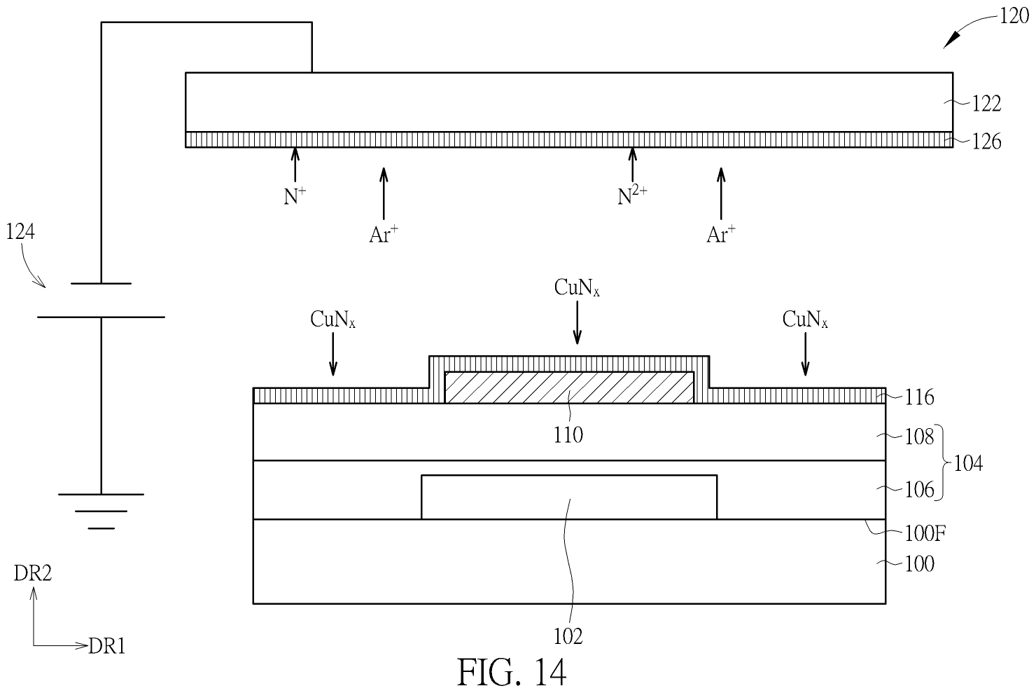

Referring to FIG. 14 to FIG. 17, FIG. 14 to FIG. 17 are schematic cross-sectional diagrams of a manufacturing method of a thin film transistor according to a first variant embodiment of the first embodiment of the present invention, and the flowchart of the manufacturing method of the thin film transistor of the first variation of the first embodiment can also refer to FIG. 9.

As shown in FIG. 9, the steps S100, S102, S104, S106 and S108 are performed, the schematic cross-sectional diagrams corresponding to the steps S100, S102, S104 and S106 of this embodiment can refer to FIG. 1, and the schematic cross-sectional diagrams corresponding to the step S108 of this embodiment can refer to FIG. 2 and FIG. 3. The difference between this variant embodiment and the first embodiment is that the conductive layer 116 in the first embodiment includes molybdenum but the conductive layer 116 in this variant embodiment includes copper nitride.

As shown in FIG. 14, the step in FIG. 14 can be performed after the step in FIG. 1. In this variant embodiment, the copper nitride film can be formed on the gate insulating layer 104 and the semiconductor layer 110 by the reactive physical vapor deposition process 120, and the copper nitride film is used as the conductive layer 116. The details of the reactive physical vapor deposition process 120 have been introduced in the first embodiment, and will not be described again.

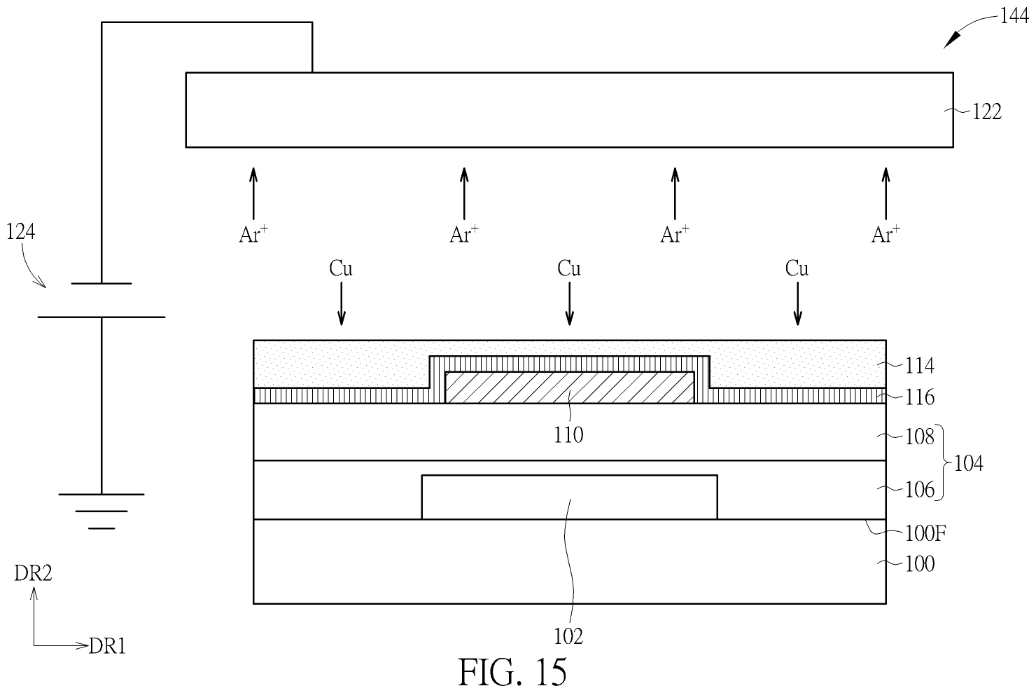

Next, as shown in FIG. 15, the conductive layer 114 can be formed by a physical vapor deposition process 144. For example, the supply of nitrogen is stopped and the supply of argon is continued after the conductive layer 116 is formed, the copper target 122 is bombarded with argon ions Art, and copper Cu is deposited on the conductive layer 116 to form the conductive layer 114. The method of forming the conductive layer 116 and the conductive layer 114 in this variant embodiment is not limited to the example in FIG. 14 and FIG. 15. In addition, the method of forming the covering layer 118 in this variant embodiment can refer to the first embodiment, and will not be described again.

Next, as shown in FIG. 9, the step S110 is performed to perform the patterning process 128 on the source/drain conductive layer 112 to pattern the conductive layers 114 and 116 and the covering layer 118 to respectively form the conductive layers 114P and 116P and the covering layer 118P. The schematic cross-sectional diagram corresponding to the step S110 of this embodiment can refer to FIG. 5.

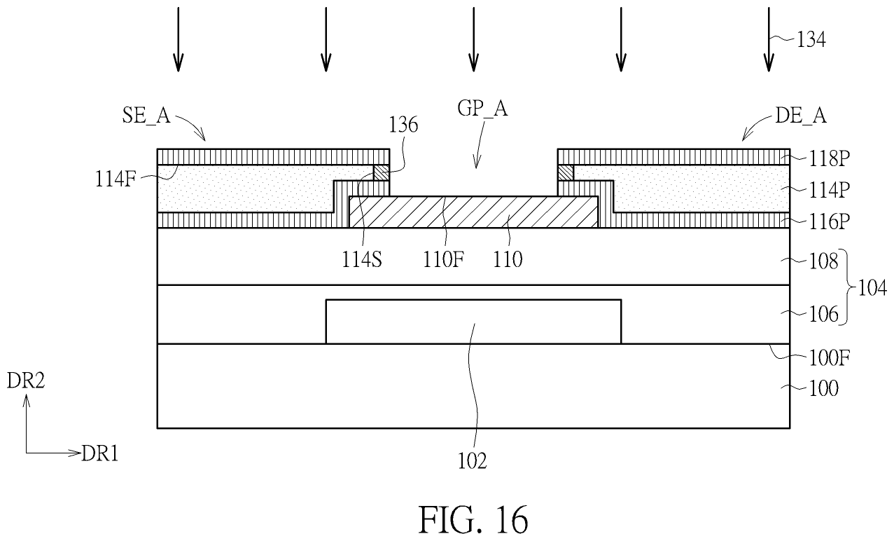

Next, as shown in FIG. 16 and FIG. 9, the step S112 is performed to perform the nitridation treatment 134. The nitridation process 134 can form the sidewall protection layer 136 on the side surface 114S of the conductive layer 114P, and the sidewall protection layer 136 includes copper nitride. After the nitridation treatment 134 is performed, the fabrication of a drain DE_A and a source SE_A of the thin film transistor may be completed. The drain DE_A and the source SE_A are opposite to each other and a gap GP_A is located between the drain DE_A and the source SE_A, and each of the drain DE_A and the source SE_A can include the conductive layers 114P, 116P, the covering layer 118P and the sidewall protection layer 136.

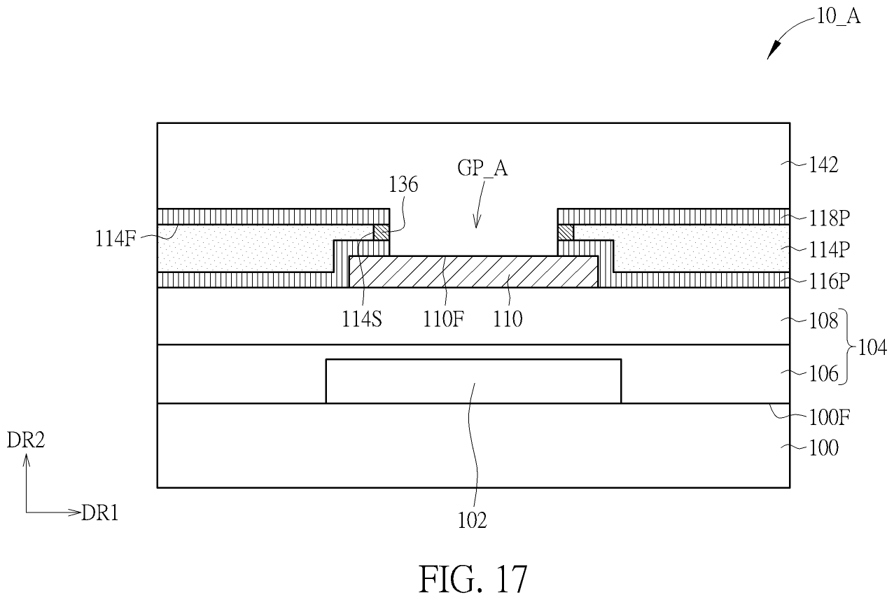

Next, as shown in FIG. 9, the steps S114 and S116 are sequentially performed, that is, the oxygen-containing repairing treatment 140 and the step of forming the insulating layer 142 in the steps S114 and S116 are sequentially performed to form a thin film transistor 10_A in FIG. 17. As shown in FIG. 17, in this embodiment, each of the conductive layer 116P and the covering layer 118P includes copper nitride, the conductive layer 114P includes copper, and the sidewall protection layer 136 on the side surface 114S of the conductive layer 114P includes copper nitride. In addition, the insulating layer 142 is disposed on the drain DE_A, the source SE_A (see FIG. 16 for DE_A and SE_A) and the semiconductor layer 110 and in the gap GP_A between the drain DE_A and the source SE_A.

Since the conductive layer 116P is disposed between the conductive layer 114P and the semiconductor layer 110, and the conductive layer 116P includes copper nitride, the conductive layer 116P can be used as the barrier layer to mitigate the phenomenon that copper in the conductive layer 114P diffuses to the semiconductor layer 110, thereby improving the electrical characteristics of the thin film transistor.

Next, the manufacturing method of the thin film transistor of the first variant embodiment of the second embodiment of the present invention will be described, and the flowchart of the manufacturing method of the thin film transistor of the first variant embodiment of the second embodiment can also refer to FIG. 9.

As shown in FIG. 9, the steps S100, S102, S104, S106 and S108 are performed, the schematic cross-sectional diagrams corresponding to the steps S100, S102, S104 and S106 of this embodiment can refer to FIG. 1, and the schematic cross-sectional diagram corresponding to the step S108 of this embodiment can refer to FIG. 10. The difference between this variant embodiment and the second embodiment is that the conductive layer 116 in the second embodiment includes molybdenum but the conductive layer 116 in this variant embodiment includes copper nitride.

Next, the step S110 shown in FIG. 9 is performed, and the schematic cross-sectional diagram of the step S110 in this variant embodiment can refer to FIG. 11. The patterning process 128 is performed on the source/drain conductive layer 112A to pattern the conductive layers 114 and 116 to respectively form the conductive layers 114P and 116P.

Next, as shown in FIG. 9, the step S112 is performed to perform the nitridation treatment 134. The schematic cross-sectional diagram of the step S112 of this variant embodiment can refer to FIG. 16. The nitridation treatment 134 can form the covering layer 118P on the upper surface 114F of the conductive layer 114P and the sidewall protection layer 136 on the side surface 114S of the conductive layer 114P simultaneously, and each of the covering layer 118P and the sidewall protection layer 136 includes copper nitride. After the nitridation treatment 134 is performed, the fabrication of the drain DE_A and the source SE_A of the thin film transistor may be completed. The drain DE_A and the source SE_A are opposite to each other and the gap GP_A is located between the drain DE_A and the source SE_A, and each of the drain DE_A and the source SE_A can include the conductive layers 114P, 116P, the covering layer 118P and the sidewall protection layer 136.

Next, as shown in FIG. 9, the steps S114 and S116 are sequentially performed, that is, the oxygen-containing repairing treatment 140 and the step of forming the insulating layer 142 in the steps S114 and S116 are sequentially performed to form the thin film transistor 10_A in FIG. 17.

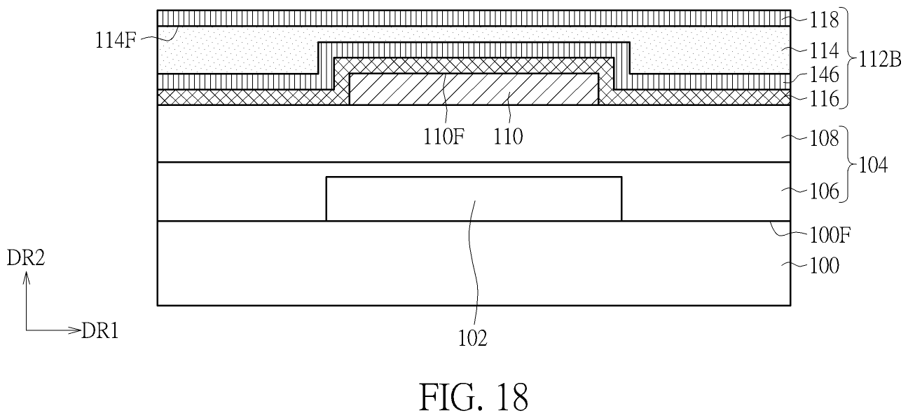

Referring to FIG. 18 to FIG. 21, FIG. 18 to FIG. 21 are schematic cross-sectional diagrams of a manufacturing method of a thin film transistor according to a second variant embodiment of the first embodiment of the present invention, and the flowchart of the manufacturing method of the thin film transistor of the second variant embodiment of the first embodiment can also refer to FIG. 9. Different from the first embodiment, a conductive layer 146 is disposed between the conductive layer 116 and the conductive layer 114 in this embodiment, and the conductive layer 146 includes copper nitride. In this disclosure, the conductive layer 146 may be referred to as the third conductive layer.

As shown in FIG. 9, the steps S100, S102, S104, S106 and S108 are performed, the schematic cross-sectional diagrams corresponding to the steps S100, S102, S104 and S106 of this embodiment can refer to FIG. 1.

Next, as shown in FIG. 18 and FIG. 9, the step S108 is performed to form the source/drain conductive layer 112B on the gate insulating layer 104 and the semiconductor layer 110. The source/drain conductive layer 112B includes the covering layer 118, the conductive layer 114, the conductive layer 146 and the conductive layer 116. The conductive layer 146 is disposed between the conductive layer 114 and the conductive layer 116, and the conductive layer 146 includes copper nitride. For example, the conductive layer 146 can be formed on the conductive layer 116 by the reactive physical vapor deposition process 120, but not limited thereto. The conductive layer 116 includes molybdenum, but not limited thereto. The conductive layer 116 may include other suitable metals or alloys.

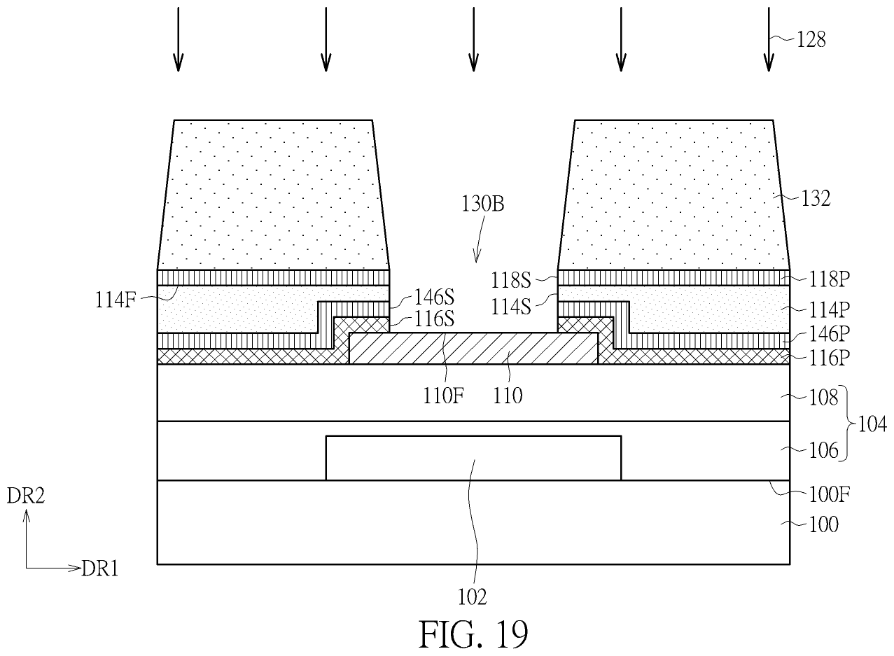

Next, as shown in FIG. 19 and FIG. 9, the step S110 is performed to perform the patterning process 128 on the source/drain conductive layer 112B to pattern the conductive layers 114, 146 and 116 and the covering layer 118 to respectively form the conductive layers 114P, 146P and 116P and the covering layer 118P. In this disclosure, the conductive layers 114, 146 and 116 and the covering layer 118 have yet been etched can respectively be referred to as the conductive material layers 114, 146 and 116 and the covering material layer 118. The patterning process 128 forms a trench 130B in the source/drain conductive layer 112B. The trench 130B penetrates through the source/drain conductive layer 112B (i.e., penetrating through the conductive layers 114, 146, and 116 and the covering layer 118), and the trench 130B exposes the side surface 116S of the conductive layer 116P, the side surface 146S of the conductive layer 146P, the side surface 114s of the conductive layer 114P, the side surface 118S of the covering layer 118P and a portion of the upper surface 110F of the semiconductor layer 110.

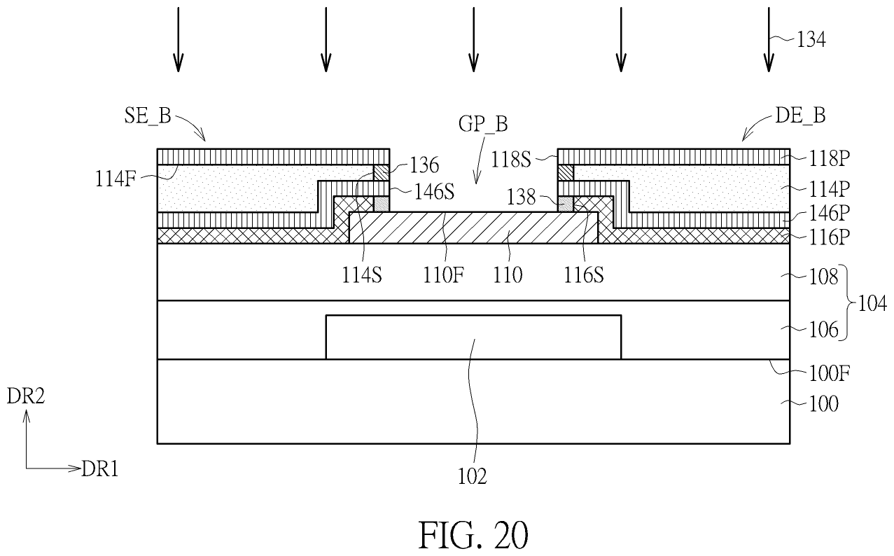

Next, as shown in FIG. 20 and FIG. 9, the step S112 is performed to perform the nitridation treatment 134. The nitridation treatment 134 can form the sidewall protection layer 136 on the side surface 114S of the conductive layer 114P and the sidewall protection layer 138 on side surface 116S of conductive layer 116P. The sidewall protection layer 136 includes copper nitride and the sidewall protection layer 138 includes molybdenum nitride, but the material of the sidewall protection layer 138 is not limited thereto. After the nitridation treatment 134 is performed, the fabrication of the drain DE_B and the source SE_B of the thin film transistor may be completed. The drain DE_B and the source SE_B are opposite to each other and a gap GP_B is located between the drain DE_B and the source SE_B, and each of the drain DE_B and the source SE_B can include the conductive layers 114P, 116P, 146P, the covering layer 118P and the sidewall protection layers 136, 138.

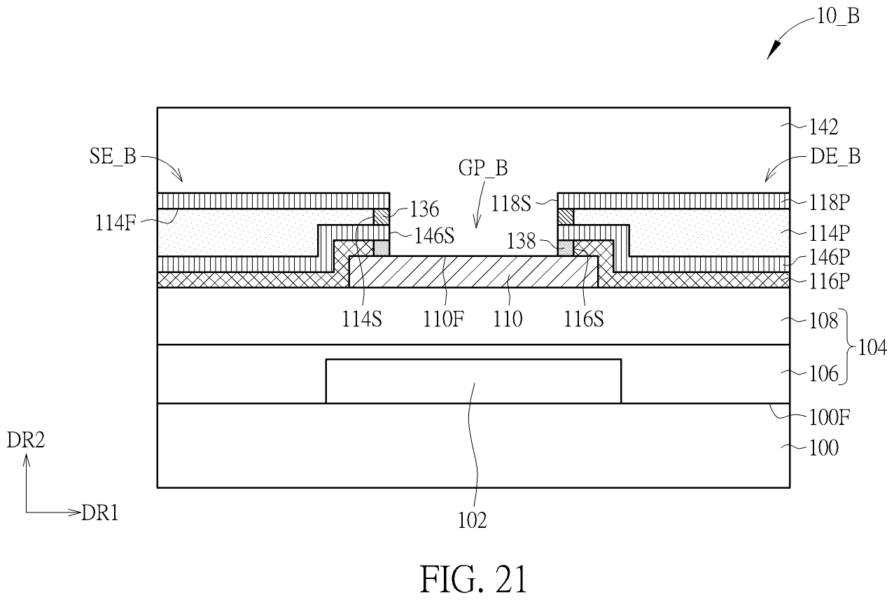

Next, as shown in FIG. 9, the steps S114 and S116 are sequentially performed, that is, the oxygen-containing repairing treatment 140 and the step of forming the insulating layer 142 in the steps S114 and S116 are sequentially performed to form a thin film transistor 10_B in FIG. 21. As shown in FIG. 21, the insulating layer 142 is disposed on the drain DE_B, the source SE_B and the semiconductor layer 110 and in the gap GP_B between the drain DE_B and the source SE_B.

In this embodiment, the conductive layer 146P is disposed between the conductive layer 116P and the conductive layer 114P, and the conductive layer 116P and the conductive layer 146P can be used as double barrier layers to mitigate the phenomenon that copper in the conductive layer 114P diffuses to the semiconductor layer 110, thereby improving the electrical characteristics of the thin film transistor.

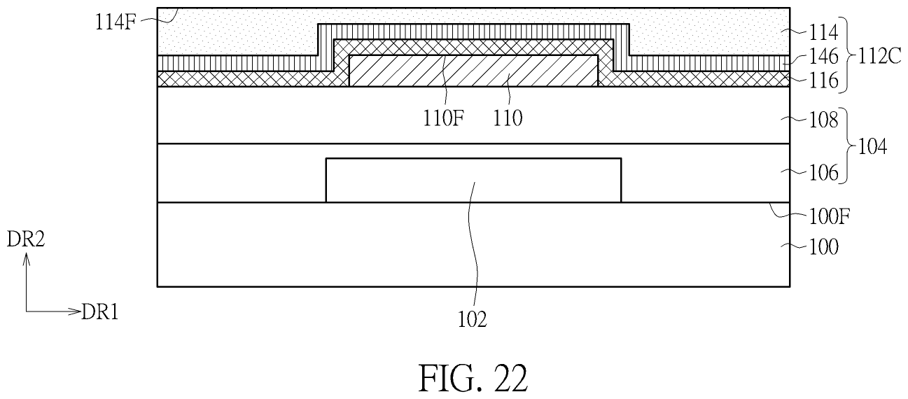

Referring to FIG. 22 to FIG. 24, FIG. 22 to FIG. 24 are schematic cross-sectional diagrams of a manufacturing method of a thin film transistor according to a second variant embodiment of the second embodiment of the present invention, and the flowchart of the manufacturing method of the thin film transistor in the second variant embodiment of the second embodiment can also refer to FIG. 9. Different from the second embodiment, the conductive layer 146 is disposed between the conductive layer 116 and the conductive layer 114 in this embodiment, and the conductive layer 146 includes copper nitride.

As shown in FIG. 9, the steps S100, S102, S104 and S106 are performed, the schematic cross-sectional diagrams corresponding to the steps S100, S102, S104 and S106 of this embodiment can refer to FIG. 1.

Next, as shown in FIG. 22 and FIG. 9, the step S108 is performed to form a source/drain conductive layer 112C on the gate insulating layer 104 and the semiconductor layer 110. The source/drain conductive layer 112C includes the conductive layer 114, the conductive layer 146 and the conductive layer 116, the conductive layer 146 is disposed between the conductive layer 114 and the conductive layer 116, and the conductive layer 146 includes copper nitride. The conductive layer 116 includes molybdenum, but not limited thereto. The conductive layer 116 may include other suitable metals or alloys.

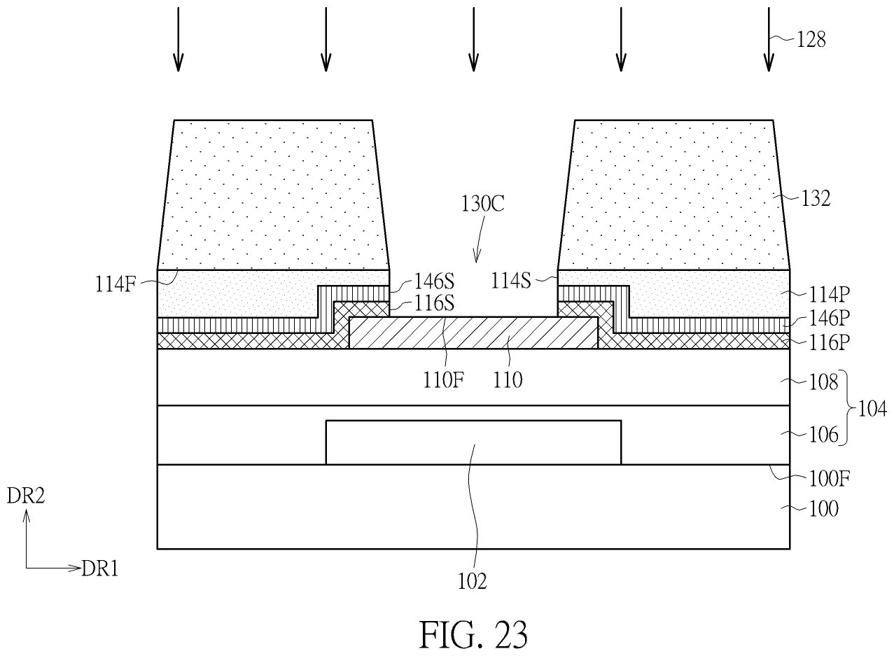

Next, as shown in FIG. 23 and FIG. 9, the step S110 is performed to perform the patterning process 128 on the source/drain conductive layer 112C to pattern the conductive layers 114, 146 and 116 to respectively form the conductive layers 114P, 146P and 116P. The patterning process 128 forms a trench 130C in the source/drain conductive layer 112C. The trench 130C penetrates through the source/drain conductive layer 112C (i.e., penetrating through the conductive layers 114, 146 and 116), and the trench 130C exposes the side surface 114S of the conductive layer 114P, the side surface 116S of the conductive layer 116P, the side surface 146S of the conductive layer 146P and a portion of the upper surface 110F of the semiconductor layer 110F.

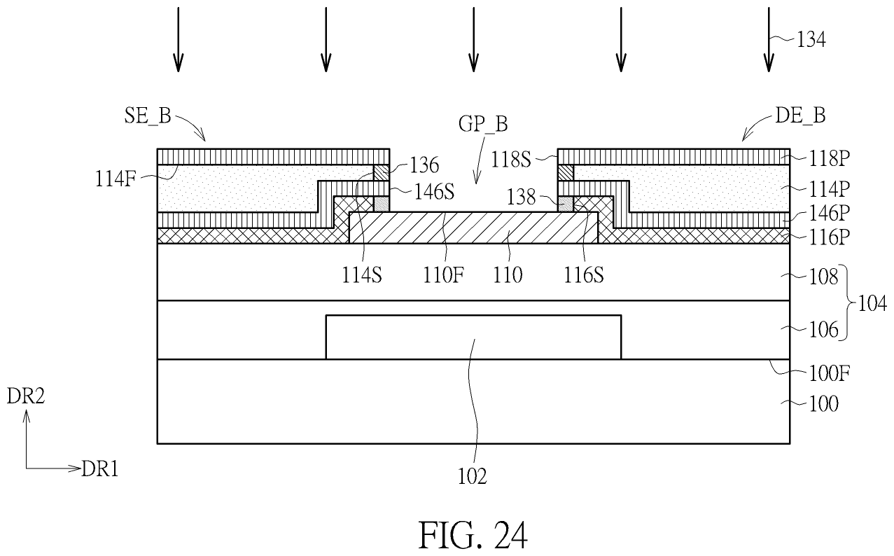

Next, as shown in FIG. 24 and FIG. 9, the step S112 is performed to perform the nitridation treatment 134. The nitridation treatment 134 may form the covering layer 118P on the upper surface 114F of the conductive layer 114P, and the sidewall protection layers 136 and 138 respectively on the side surface 114S of the conductive layer 114P and the side surface 116S of the conductive layer 116P. Each of the covering layer 118 and the sidewall protection layer 136 includes copper nitride, and the sidewall protection layer 138 includes molybdenum nitride, but the material of the sidewall protection layer 138 is not limited thereto. After the nitridation treatment 134 is performed, the fabrication of the drain DE_B and the source SE_B of the thin film transistor may be completed. The drain DE_B and the source SE_B are opposite to each other and the gap GP_B is located between the drain DE_B and the source SE_B, and each of the drain DE_B and the source SEB can include the conductive layers 114P, 116P, 146P, the covering layer 118P and the sidewall protection layers 136, 138.

Next, as shown in FIG. 9, the steps S114 and S116 are sequentially performed, that is, the oxygen-containing repairing treatment 140 and the step of forming the insulating layer 142 in the steps S114 and S116 are sequentially performed to form the thin film transistor 10_B in FIG. 21.

In summary, in the thin film transistor and the manufacturing method thereof of the present invention, the copper nitride layer is formed above, below or on the side surface of the copper layer of the source and drain as the covering layer, the barrier layer or the sidewall protection layer, which can mitigate the oxidation and diffusion of copper and further improve the electrical characteristics of the thin film transistor. Using the copper nitride layer as the covering layer can prevent the edge of the covering layer from forming the chamfer due to etching and reduce the holes or cracks in the thin film transistor, thereby improving the reliability of the thin film transistor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a thin film transistor, comprising:
providing a substrate;
forming a gate on the substrate;
forming a gate insulating layer on the gate;
forming a semiconductor layer on the gate insulating layer;
forming a source/drain conductive layer on the gate insulating layer and the semiconductor layer, wherein the source/drain conductive layer comprises a first conductive layer and a covering layer, the covering layer is disposed on an upper surface of the first conductive layer, the first conductive layer comprises copper, and the covering layer comprises copper nitride; and
performing a patterning process to form a trench in the source/drain conductive layer, and the trench penetrates through the source/drain conductive layer.

2. The manufacturing method of the thin film transistor according to claim 1, wherein after the first conductive layer is formed and before the patterning process is performed, a reactive physical vapor deposition process is performed to form the covering layer on the upper surface of the first conductive layer, the reactive physical vapor deposition process is performed in a physical vapor deposition apparatus, and the reactive physical vapor deposition process comprises:
providing a copper target;
providing nitrogen and forming copper nitride on the copper target; and
providing argon and bombarding the copper nitride on the copper target with argon ions, and forming the covering layer on the upper surface of the first conductive layer.

3. The manufacturing method of the thin film transistor according to claim 1, further comprising performing a nitridation treatment, wherein the nitridation treatment is performed after the patterning process is performed.

4. The manufacturing method of the thin film transistor according to claim 3, wherein the trench exposes a side surface of the first conductive layer, a sidewall protection layer is formed on the side surface of the first conductive layer by the nitridation treatment, and the sidewall protection layer comprises copper nitride.

5. The manufacturing method of the thin film transistor according to claim 3, further comprising forming an insulating layer, wherein the insulating layer comprises oxygen, and the insulating layer is formed after the nitridation treatment is performed.

6. The manufacturing method of the thin film transistor according to claim 5, further comprising performing an oxygen-containing repairing treatment, wherein the oxygen-containing repairing treatment is performed after the nitridation treatment is performed and before the insulating layer is formed.

7. The manufacturing method of the thin film transistor according to claim 1, wherein the source/drain conductive layer further comprises a second conductive layer, the first conductive layer is disposed on the second conductive layer, and the second conductive layer comprises molybdenum or copper nitride.

8. The manufacturing method of the thin film transistor according to claim 7, wherein the second conductive layer comprises the molybdenum, the source/drain conductive layer further comprises a third conductive layer, the third conductive layer is disposed between the second conductive layer and the first conductive layer, and the third conductive layer comprises copper nitride.

9. A manufacturing method of a thin film transistor, comprising:
providing a substrate;
forming a gate on the substrate;
forming a gate insulating layer on the gate;
forming a semiconductor layer on the gate insulating layer;
forming a source/drain conductive layer on the gate insulating layer and the semiconductor layer, wherein the source/drain conductive layer comprises a first conductive layer, and the first conductive layer comprises copper;
performing a patterning process to form a trench in the source/drain conductive layer, and the trench penetrates through the source/drain conductive layer; and
performing a nitridation treatment, wherein the nitridation treatment forms a covering layer on an upper surface of the first conductive layer, the covering layer comprises copper nitride, and the nitridation treatment is performed after the patterning process is performed.

10. The manufacturing method of the thin film transistor according to claim 9, wherein the trench exposes a side surface of the first conductive layer, a sidewall protection layer is formed on the side surface of the first conductive layer by the nitridation treatment, and the sidewall protection layer comprises copper nitride.

11. The manufacturing method of the thin film transistor according to claim 9, further comprising forming an insulating layer, wherein the insulating layer comprises oxygen, and the insulating layer is formed after the nitridation treatment is performed.

12. The manufacturing method of the thin film transistor according to claim 11, further comprising performing an oxygen-containing repairing treatment, wherein the oxygen-containing repairing treatment is performed after the nitridation treatment is performed and before the insulating layer is formed.

13. The manufacturing method of the thin film transistor according to claim 9, wherein the source/drain conductive layer further comprises a second conductive layer, the first conductive layer is disposed on the second conductive layer, and the second conductive layer comprises molybdenum or copper nitride.

14. The manufacturing method of the thin film transistor according to claim 13, wherein the second conductive layer comprises the molybdenum, the source/drain conductive layer further comprises a third conductive layer, the third conductive layer is disposed between the second conductive layer and the first conductive layer, and the third conductive layer comprises copper nitride.

15. A thin film transistor, comprising:
a substrate;
a gate disposed on the substrate;
a gate insulating layer disposed on the gate;
a semiconductor layer disposed on the gate insulating layer; and
a drain and a source, and each of the drain and the source comprises:
a first conductive layer disposed on the semiconductor layer and the gate insulating layer, and the first conductive layer comprises copper; and
a covering layer disposed on an upper surface of the first conductive layer, and the covering layer comprises copper nitride.

16. The thin film transistor according to claim 15, wherein the each of the drain and the source further comprises a sidewall protection layer disposed on a side surface of the first conductive layer, and the sidewall protection layer comprises copper nitride.

17. The thin film transistor according to claim 15, wherein the each of the drain and the source further comprises a second conductive layer disposed between the first conductive layer and the semiconductor layer and between the first conductive layer and the gate insulating layer, and the second conductive layer comprises molybdenum or copper nitride.

18. The thin film transistor according to claim 17, wherein the second conductive layer comprises the molybdenum, and the each of the drain and the source further comprises a third conductive layer disposed between the second conductive layer and the first conductive layer, and the third conductive layer comprises copper nitride.
